(19) United States
(12) Patent Application Publication
(10) Pub. No.: US 2007/0096136 A1
(43) Pub. Date: May 3, 2007

(54) Cladding layer structure of a LED package structure

(75) Inventor: Wei-Kuo Sun, Taipei City (TW)

Correspondence Address: CHARLES E. BAXLEY, ESQ., 90 JOHN STREET, THIRD FLOOR, NEW YORK, NY, 10038, US

(73) Assignee: iLed Photoelectronics, Inc.

(21) Appl. No.: 11/584,171

(22) Filed: Oct. 20, 2006

(30) Foreign Application Priority Data
Oct. 28, 2005 (CN) 094218723

(51) Int. Cl. H01L 33/00

(52) U.S. Cl. 257/99

(57) ABSTRACT

A cladding layer structure of a LED (light emitting diode) package structure comprises a printed circuit layer arranged on a substrate, a cladding layer having a through hole is located on the printed circuit layer, a chip is received in the through hole and is in electrical contact with the printed circuit layer via a welding wire. Resin is located on the printed circuit layer and filled in the through hole of the cladding layer for sealing the chip. And an optical lens is placed on the cladding layer.

### BACKGROUND OF THE INVENTION

1. Field of the Invention

The present invention relates to the LED (light emitting diode) field, and more particularly to a cladding layer structure of a LED package structure.

2. Description of the Prior Art

In the LED (light emitting diode) technology, LED chip is adapted to generate light by cooperating with optical elements. As shown in FIG. 1, a conventional LED package structure is illustrated and comprises a substrate 10, a conductive layer 11, a chip 12, a welding wire 13, a sealing resin 14 and an optical lens 15.

The conductive layer 11 is placed on the substrate 10 and is in electrical contact with both sides of the substrate 10. The chip 12 is placed one side of the substrate 10 and is connected to the conductive layer 11 by the welding wire 13, for electrically connecting the chip 12 with outside. The sealing resin 14 is coated on the substrate 10 for covering the chip 12, the welding wire 13, and a part of the conductive layer 11. The optical lens 15 is placed on the sealing resin 14 and includes a concave surface 151 and a convex surface 152, and the concave surface faces the sealing resin 14.

However, in this conventional LED package structure, the chip is directly adhered in the cup by adhesive agent, and then is sealed with sealing resin. In application, it must use extra circuit to connect the respective LED together, the resultant disadvantage is that the illumination area is too small, which will cause shadow and faculae.

The present invention has arisen to mitigate and/or obviate the afore-described disadvantages.

### SUMMARY OF THE INVENTION

The primary objective of the present invention is to provide a cladding layer structure of a LED package structure that have the same luminance as the incandescent lamp or the Fluorescent Lamp.

The primary objective of the present invention is to provide a cladding layer structure of a LED package structure, wherein a cladding layer is provided on the substrate, so as to improve the light generating efficiency of the chip.

The present invention will become more obvious from the following description when taken in connection with the accompanying drawings, which show, for purpose of illustrations only, the preferred embodiments in accordance with the present invention.

### BRIEF DESCRIPTION OF THE DRAWINGS

FIG. 1 shows a conventional LED package structure;

FIG. 2 is a perspective view of showing a cladding layer in accordance with a first embodiment of the present invention;

FIG. 3 is a cross sectional view of a LED package structure with the cladding layer of FIG. 2;

FIG. 4 is a perspective view of showing a cladding layer in accordance with a second embodiment of the present invention;

FIG. 5 is a cross sectional view of a LED package structure with the cladding layer of FIG. 2;

FIG. 6 is a perspective view of showing the cladding layer in accordance with a third embodiment of the present invention; and

FIG. 7 is a cross sectional view of showing the sealing structure for a white light LED in accordance with the third embodiment of the present invention.

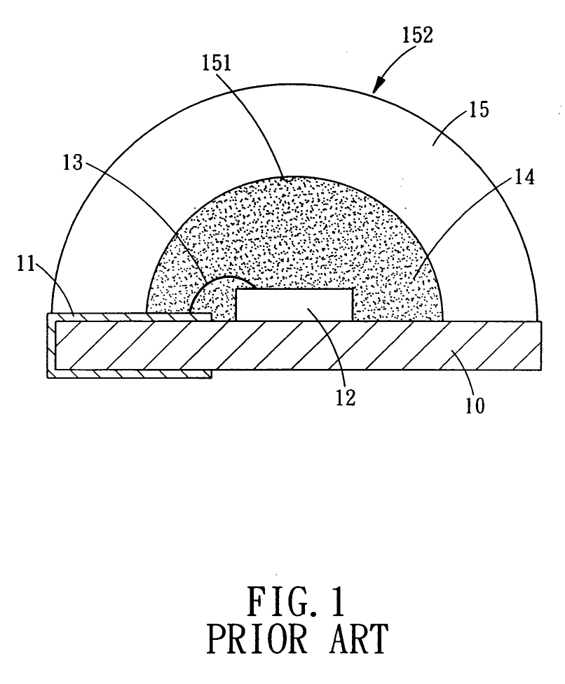

### DETAILED DESCRIPTION OF THE PREFERRED EMBODIMENTS

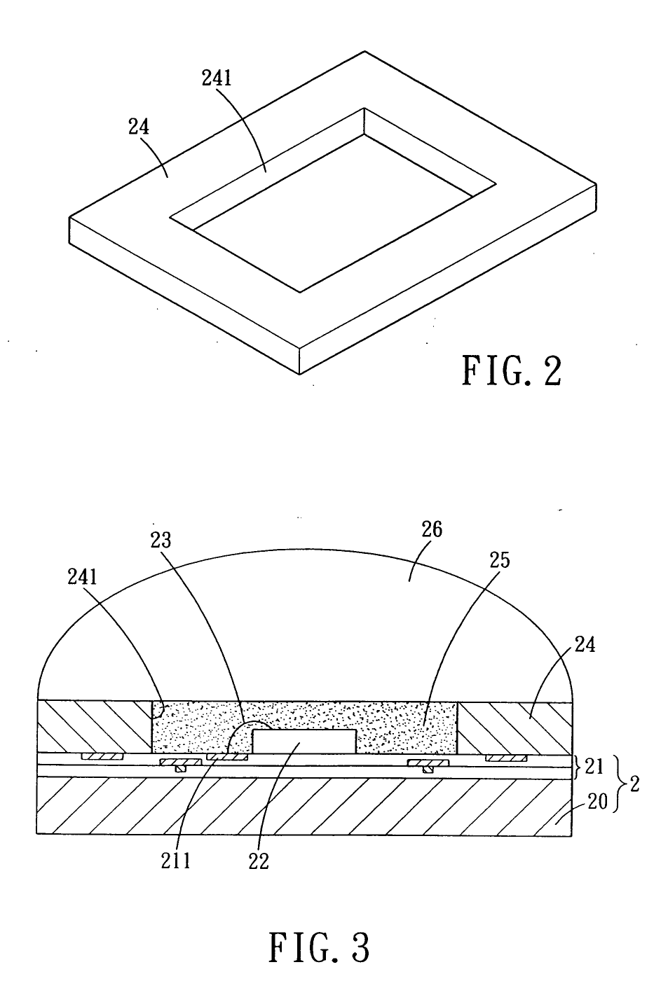

Referring to FIGS. 2 and 3, a cladding layer structure of a LED (light emitting diode) package structure in accordance with the present invention comprises: a base 2, a chip 22, a welding wire 23, a cladding layer 24, a resin 25 and an optical lens 26. A printed circuit layer 21 with an electrode-welding pad 211 is placed on the substrate 20 of the base 2, the chip 22 is located on the surface of the printed circuit layer 21, and the cladding layer 24 having a through hole 241: is also arranged on the printed circuit layer 21. The chip 22 is received in the through hole 241 of the cladding layer 24. The welding wire 23 has one end connected to the chip 22 and another end connected to the electrode welding pad 211 of the printed circuit layer 22. The resin 25 is filled in the through hole 241 to seal the chip 22 and the welding wire 23. The optical lens 26 is larger than the through hole 241 and is mounted on the surface of the cladding layer 24.

The sealing structure for a white light LED (light emitting diode) in accordance with this embodiment utilizes the through hole of the cladding layer to receive the chip.

Besides, a plurality of chips are received in the through holes of the cladding layer, and the sidewall of the whole cladding layer is utilized to improve the light generating efficiency of the chip.

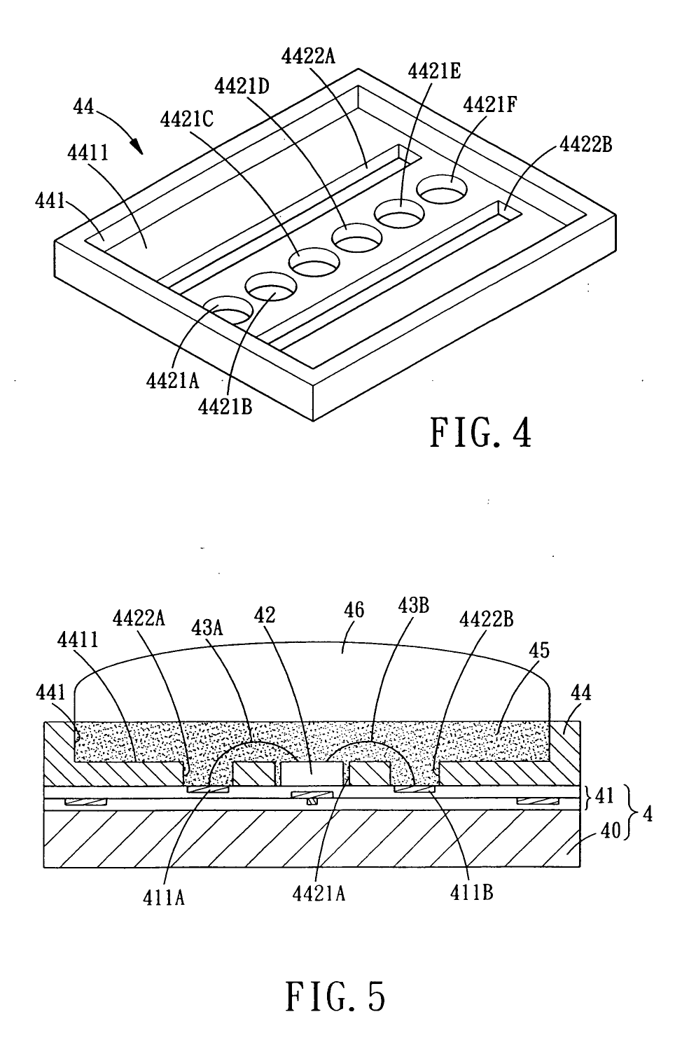

Referring to FIGS. 4 and 5, FIG. 4 is a perspective view of showing a cladding layer in accordance with a second embodiment of the present invention, and FIG. 5 is a cross sectional view of a LED package structure with the cladding layer of FIG. 4. This embodiment is slightly different from the previous embodiment shown in FIGS. 2 and 3, and the differences are described below:

Referring firstly to FIG. 4, a recess 441 is formed in the cladding layer 44, and the recess 341 has a flat bottom 4411. Six through holes 4421A, 4421B, 4421C, 4421D, 4421E and 4421F are arranged in line and defined in the center of the bottom 4411 of the recess 441. An elongated through hole 4422A, 4422B is defined at either side of the line of the through holes 4421A, 4421B, 4421C, 4421D, 4421E and 4421F.

The through holes 4422A and 4422B are adapted to receive the electrode welding pads 411A and 411B the printed circuit layer 41, and the electrode welding pads 411A and 411B will protrude out of the through holes 4422A and 4422B when the cladding layer 44 is placed on the printed circuit layer 41.

As shown in FIG. 5, the difference of this embodiment with respect to the first embodiment as shown in FIG. 3 is the structure and the arrangement of the cladding layer 44 and the chip 42.

In this embodiment, the cladding layer 44 is located on the printed circuit layer 41 in such a manner that the electrode welding pads 411A and 411B protrude out of the through holes 4422A and 4422B. The chip 42 is received in the through hole 4421A. The welding wires 43A and 43B each has one end connected to the chip 42 and another end connected to the electrode welding pads 411A and 411B on the printed circuit layer 41 via the through holes 4422A and 4422B.

The resin 45 is filled in the recess 441 and the respective through holes 4421A, 4422A and 4422B to seal the chip 42, the electrode welding pads 411A and 411B, and the welding wires 43A and 43B. And an optical lens 46 is placed on the cladding layer 44.

The through hole 4421A in this embodiment is described above for purposes of example only, and in fact, each of the through holes 4421A, 4421B, 4421C, 4421D, 4421E and 4421F is received with a chip 42, and each chip 42 is provided with a welding wire 43A and 43B.

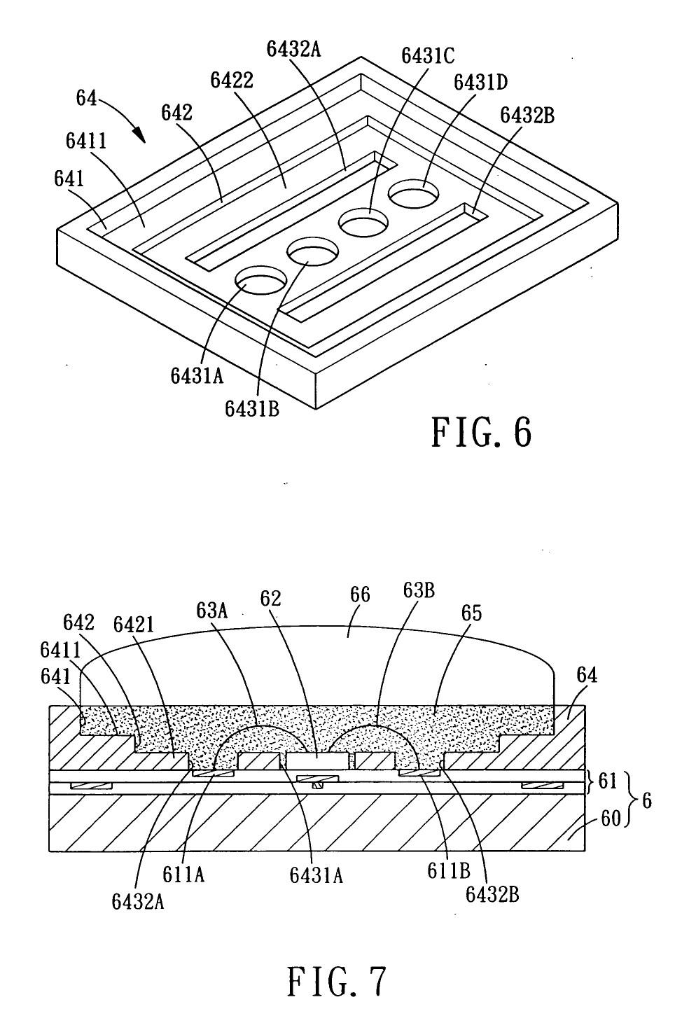

Referring then to FIGS. 6 and 7, FIG. 6 is a perspective view of showing the cladding layer in accordance with a third embodiment of the present invention, and FIG. 7 is a cross sectional view of showing the sealing structure for a white light LED in accordance with the third embodiment of the present invention. This embodiment is slightly different from the first embodiment, and the differences are described as follows:

As shown in FIG. 6, a first recess 641 with a predetermined depth is defined in the surface of the cladding layer 64, and a second recess 642 smaller than first recess 641 is formed in the bottom 6411 of the first recess 642. Four through holes 6431A, 6431B, 6431C and 6431D are arranged in line and defined in the center of the bottom 6421 of the second recess 642. A rectangular through hole 6432A and 6432B is defined at either side of the line of the through holes 6431A, 6431B, 6431C and 6431D.

As shown in FIG. 7, two electrode welding pads 611A and 611B are arranged on the surface of the printed circuit layer 61 and are located correspondingly to the rectangular through holes 6432A and 6432B, and the electrode welding pads 611A and 611B will protrude out of the through holes 6432A and 6432B when the cladding layer 64 is placed on the surface 61 of the printed circuit 602.

The chip 62 is positioned in the through hole 6431A and is connected to the electrode welding pads 611A and 611B by the welding wires 63A and 63B, respectively. The resin 65 is filled in the second recess 642 and the through holes 6431A, 6431B, 6431C and 6431D, so as to seal the bottom 642, the welding wires 63A and 63B, and the chip 62. And then an optical lens 66 larger than the first recess 641 is placed on the cladding layer, thus forming a LED package structure.

According to the abovementioned cladding layer structure of the LED package structure, the cladding layer having through holes are located on the base, and the chips are received in the through holes. By such arraignments, a single LED structure has a plurality of light emitting chips, and it will have the same luminance as the incandescent lamp or the Fluorescent Lamp. Furthermore, the through holes in the cladding layer are used for holding the chips, thus improving stability.

In addition, the inner wall of the through holes for holding the chips can be inclined, so that the light generated by the chips will be reflected, and thus the luminance of the chips will be improved to the same level as the incandescent lamp or the Fluorescent Lamp.

While we have shown and described various embodiments in accordance with the present invention, it should be clear to those skilled in the art that further embodiments may be made without departing from the scope of the present invention.

What is claimed is:

1. A cladding layer structure of a LED (light emitting diode) package structure comprising:
a base including a printed circuit layer located on a substrate, and at least one electrode welding pad arranged on the printed circuit;
a cladding layer with at least one through hole being located on the printed circuit layer;
at least one chip being placed on the base and in electrical contact with the printed circuit layer; and
resin being located on the printed circuit layer and filled in the through hole of the cladding layer, for sealing the chip.

2. The cladding layer structure of a LED (light emitting diode) package structure as claimed in claim 1 further comprising a layer located on the cladding layer.

3. The cladding layer structure of a LED (light emitting diode) package structure as claimed in claim 2, wherein the layer located on the cladding layer is selected from the group consisted of transparent film, optical lens, and optical component.

4. The cladding layer structure of a LED (light emitting diode) package structure as claimed in claim 2, wherein the layer located on the cladding layer is larger than the through hole of the cladding layer.

5. The cladding layer structure of a LED (light emitting diode) package structure as claimed in claim 1 further comprising a welding wire for electrically connecting the chip with the printed circuit layer, and the welding wire is encapsulated by the rein.

6. The cladding layer structure of a LED (light emitting diode) package structure as claimed in claim 1, wherein the chip is placed on the surface of the substrate.

7. The cladding layer structure of a LED (light emitting diode) package structure as claimed in claim 1, wherein the chip is placed on the surface of the printed circuit layer.
